(19) United States
(12) Patent Application Publication
(10) Pub. No.: US 2018/0090927 A1
(43) Pub. Date: Mar. 29, 2018

(54) INTEGRATED CIRCUIT AND OPERATION METHOD THEREOF

(71) Applicant: ALi Corporation, Hsinchu (TW)

(72) Inventors: Bing-You Gao, Taipei City (TW); Chuan-Sheng Lee, Taipei City (TW)

(73) Assignee: ALi Corporation, Hsinchu (TW)

(21) Appl. No.: 15/382,445

(22) Filed: Dec. 16, 2016

(30) Foreign Application Priority Data
Sep. 29, 2016 (CN) 201610862322.6

(51) Int. Cl. H02H 9/04; H01L 27/02

(52) U.S. Cl. CPC H02H 9/046; H01L 27/0288; H01L 27/0292; H01L 27/027

(57) ABSTRACT

An integrated circuit (IC) and an operation method thereof are provided. The IC includes a first voltage rail, a second voltage rail, an electrostatic discharge (ESD) clamp circuit, a capacitor and a resistive element. A control terminal of the ESD clamp circuit receives a control signal during an ESD period, and the ESD clamp circuit provides an ESD current path between the first voltage rail and the second voltage rail. The capacitor is coupled between the control terminal and the second voltage rail. The resistive element is coupled between the control terminal and the first voltage rail. During a normal operation period, a resistance of the resistive element is a first resistance. During the ESD period, the resistance of the resistive element is a second resistance. The first resistance is smaller than the second resistance.

### CROSS-REFERENCE TO RELATED APPLICATION

This application claims the priority benefit of China application serial no. 201610862322.6, filed on Sep. 29, 2016. The entirety of the above-mentioned patent application is hereby incorporated by reference herein and made a part of this specification.

### BACKGROUND OF THE INVENTION

### Field of the Invention

The invention relates to an integrated circuit and an operation method thereof.

### Description of Related Art

Regardless in a manufacturing process or in an actual use, electrostatic current may unexpectedly flow into an integrated circuit (IC), i.e. an electrostatic discharge (ESD) event occurs in the IC. When an ESD current/voltage is far greater than a sustainable current/voltage of an electronic component, the ESD current may damage a function circuit (a core circuit) of the IC. In order to prevent the ESD current from causing component damage, an ESD protection circuit is generally configured in the IC to protect the electronic components. In the known ESD protection circuit, during an ESD period, a RC inverter may detect whether a voltage rail or a power ring has an ESD event, so as to determine whether to activate an ESD clamp circuit in the ESD protection circuit in time. During a normal operation period, the RC inverter is in an idle state.

Moreover, in order to decrease coupling noises, plenty decoupling capacitors are generally configured in the IC. The decoupling capacitors are connected across different voltage rails (or power rings) to filter out the coupling noise of the voltage rails (or the power rings).

### SUMMARY OF THE INVENTION

The invention is directed to an integrated circuit and an operation method thereof, where during a normal operation period, a capacitor in an electrostatic discharge (ESD) protection circuit is used as a decoupling capacitor, and an ESD protection function is provided during an ESD period.

An embodiment of the invention provides an integrated circuit including a first voltage rail, a second voltage rail, an ESD clamp circuit, a capacitor and a resistive element. The first voltage rail transmits a first voltage during a normal operation period. The second voltage rail transmits a second voltage during the normal operation period. The ESD clamp circuit has a control terminal, and the control terminal receives a control signal during an ESD period, such that the ESD clamp circuit provides an ESD current path between the first voltage rail and the second voltage rail. The capacitor is coupled between the control terminal and the second voltage rail. The resistive element is coupled between the control terminal and the first voltage rail. During the normal operation period, a resistance of the resistive element is a first resistance. During the ESD period, the resistance of the resistive element is a second resistance. The first resistance is smaller than the second resistance.

An embodiment of the invention provides an operation method of an integrated circuit. The integrated circuit includes a first voltage rail, a second voltage rail, an ESD clamp circuit, a capacitor and a resistive element. The ESD clamp circuit is coupled between the first voltage rail and the second voltage rail. The resistive element is coupled between the first voltage rail and a control terminal of the ESD clamp circuit. The capacitor is coupled between the second voltage rail and the control terminal of the ESD clamp circuit. The operation method includes following steps. During a normal operation period, a first voltage and a second voltage are respectively transmitted through the first voltage rail and the second voltage rail, and a resistance of the resistive element is a first resistance. During an ESD period, the integrated circuit receives an electrostatic voltage, and the resistance of the resistive element is a second resistance, and a control signal is produced to the control terminal of the ESD clamp circuit, such that the ESD clamp circuit provides an ESD current path between the first voltage rail and the second voltage rail, where the first resistance is smaller than the second resistance.

According to the above description, the embodiments of the invention provide the integrated circuit and the operation method thereof. In an embodiment of the invention, during the normal operation period, the resistive element has the smaller resistance, i.e. first resistance, such that the capacitor is substantially connected between the first voltage rail and the second voltage rail, directly. Therefore, during the normal operation period, the capacitor can be used as a decoupling capacitor. During the ESD period, the resistive element has the larger resistance, i.e. second resistance. Therefore, during the ESD period, the resistive element and the capacitor coupled in series may inspect whether the first voltage rail or the second voltage rail has an ESD event, so as to determine whether to activate the ESD clamp circuit in time, and accordingly provide the ESD protection function.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit block schematic diagram of an integrated circuit (IC) according to an embodiment of the invention.

FIG. 2 is a circuit schematic diagram of an electrostatic discharge (ESD) clamp circuit, a capacitor and a resistive element of FIG. 1 according to an embodiment of the invention.

FIG. 3 is a circuit schematic diagram of the ESD clamp circuit, the capacitor and the resistive element of FIG. 1 according to another embodiment of the invention.

FIG. 4 is a circuit schematic diagram of the ESD clamp circuit, the capacitor and the resistive element of FIG. 1 according to still another embodiment of the invention.

FIG. 5 is a circuit schematic diagram of the ESD clamp circuit, the capacitor and the resistive element of FIG. 1 according to still another embodiment of the invention.

### DESCRIPTION OF EMBODIMENTS

A term “couple” used in the full text of the disclosure (including the claims) refers to any direct and indirect connections. For example, if a first device is described to be coupled to a second device, it is interpreted as that the first device is directly connected to the second device, or the first device is indirectly connected to the second device through other devices or connection means. Moreover, wherever possible, components/members/steps using the same referential numbers in the drawings and description refer to the same or like parts. Components/members/steps using the same referential numbers or using the same terms in different embodiments may cross-refer related descriptions.

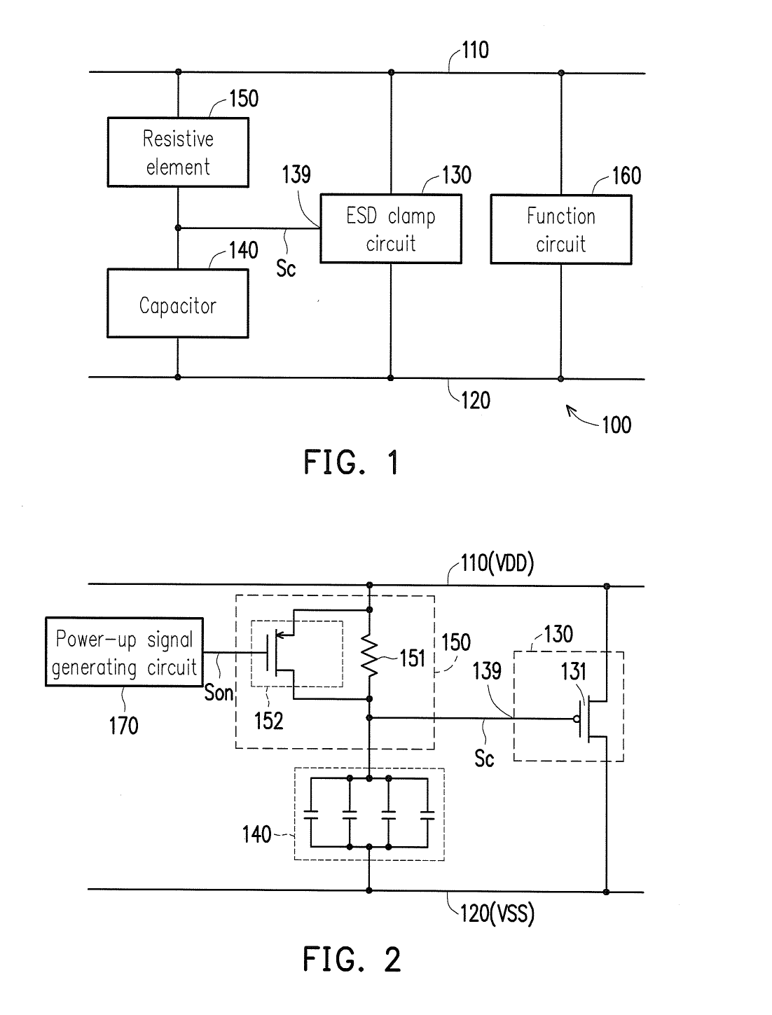

FIG. 1 is a circuit block schematic diagram of an integrated circuit (IC) 100 according to an embodiment of the invention. The IC 100 includes a first voltage rail 110, a second voltage rail 120, an electrostatic discharge (ESD) clamp circuit 130, a capacitor 140 and a resistive element 150. During a normal operation period, the first voltage rail 110 and the second voltage rail 120 may supply power to a function circuit (a core circuit) 160. For example, during the normal operation period, a first voltage transmitted by the first voltage rail 110 can be a system voltage (for example, 3.3 V, 5 V or other voltage level), and a second voltage transmitted by the second voltage rail 120 can be a ground voltage (for example, 0 V or other voltage level). In some other embodiments, the first voltage transmitted by the voltage rail 110 can be the ground voltage, and the second voltage transmitted by the second voltage rail 120 can be the system voltage.

The resistive element 150 is coupled between a control terminal 139 of the ESD clamp circuit 130 and the first voltage rail 110. The capacitor 140 is coupled between the control terminal 139 and the second voltage rail 120. During the normal operation period, a resistance of the resistive element 150 is a smaller first resistance. The first resistance can be determined according to an actual design requirement. For example, the first resistance can be 0 ohm, several ohms or tens of ohms. Therefore, during the normal operation period, the capacitor 140 is substantially connected between the first voltage rail 110 and the second voltage rail 120, directly. Therefore, the capacitor 140 can be used as a decoupling capacitor during the normal operation period. The decoupling capacitor connected across the first voltage rail 110 and the second voltage rail 120 may filter a coupling noise.

The resistive element 150 and the capacitor 140 construct a RC circuit for inspecting ESD. During a non-normal operation period (the ESD period), the resistance of the resistive element 150 is a second resistance (a larger resistance, i.e. the second resistance is greater than the first resistance). The second resistance can be determined according to an actual design requirement. For example, the second resistance can be several million ohms. When the ESD event occurs, the RC circuit may generate a control signal Sc to control the ESD clamp circuit 130. For example, when an ESD pulse occurs on the first voltage rail 110 or the second voltage rail 120, a cross voltage between two terminals of the resistive element 150 may serve as the control signal Sc. When the control terminal 139 receives the control signal Sc during the ESD period, the ESD clamp circuit 130 may provide at least one ESD current path between the first voltage rail 110 and the second voltage rail 120. The ESD current path may guide an ESD current from the first voltage rail 110 to the second voltage rail 120, or guide the ESD current from the second voltage rail 120 to the first voltage rail 110. Therefore, the function circuit (the core circuit) 160 is avoided to be damaged by the ESD current.

FIG. 2 is a circuit schematic diagram of the ESD clamp circuit 130, the capacitor 140 and the resistive element 150 of FIG. 1 according to an embodiment of the invention. In the embodiment of FIG. 2, during the normal operation period, the first voltage transmitted by the first voltage rail 110 can be a system voltage VDD, and the second voltage transmitted by the second voltage rail 120 can be a ground voltage VSS.

In the embodiment of FIG. 2, the ESD clamp circuit 130 may include a transistor 131. In the embodiment of FIG. 2, the transistor 131 can be a P-channel metal oxide semiconductor (PMOS) transistor, though the invention is not limited thereto. A first terminal (for example, a source) of the transistor 131 is coupled to the first voltage rail 110, a second terminal (for example, a drain) of the transistor 131 is coupled to the second voltage rail 120, and a third terminal (for example, a gate) of the transistor 131 serves as the control terminal 139 of the ESD clamp circuit 130 and is coupled to the resistive element 150. When the ESD occurs, the third terminal of the transistor 131 electrically turns on the transistor 131 according to the control signal Sc, so as to provide the ESD current path between the first voltage rail 110 and the second voltage rail 120.

In the embodiment of FIG. 2, the capacitor 140 includes a plurality of capacitors connected in parallel to each other. The number of the capacitors (or the capacitance) in internal of the capacitor 140 can be determined according to an actual design requirement. In some embodiments, the capacitor 140 may include a single capacitor.

In the embodiment of FIG. 2, the resistive element 150 includes a resistor 151 and a switch circuit 152. The resistor 151 is coupled between the control terminal 139 and the first voltage rail 110. The switch circuit 152 is coupled between the control terminal 139 and the first voltage rail 110. During the normal operation period, the switch circuit 152 is turned on. During the ESD period, the switch circuit 152 is turned off. In the embodiment of FIG. 2, the switch circuit 152 includes a PMOS transistor. In the embodiment of FIG. 2, a first terminal (for example, a drain) of the PMOS transistor is coupled to the control terminal 139, a second terminal (for example, a source) thereof is coupled to the first voltage rail 110, and a third terminal (for example, a gate) thereof is coupled to a power-up signal generating circuit 170 of the IC 100 and controlled by a power-up signal Son of the IC 100. During the normal operation period, the third terminal of the PMOS transistor receives the power-up signal Son to turn on the PMOS transistor.

The power-up signal generating circuit 170 may inspect whether the IC 100 is power-up, and accordingly generate the power-up signal Son. The power-up signal generating circuit 170 and the power-up signal Son are known techniques, and details thereof are not repeated. Based on the control of the power-up signal Son, the PMOS transistor maintains a turn-on state during the normal operation period.

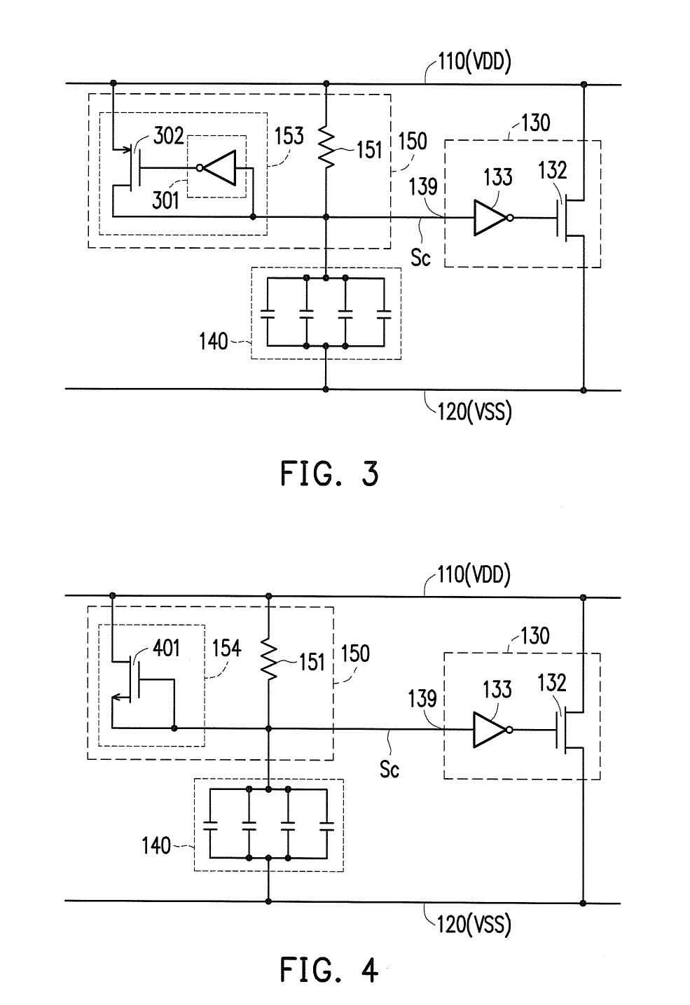

FIG. 3 is a circuit schematic diagram of the ESD clamp circuit 130, the capacitor 140 and the resistive element 150 of FIG. 1 according to another embodiment of the invention. The capacitor 140 shown in FIG. 3 may refer to related description of the embodiment of FIG. 2, and detail thereof is not repeated. In the embodiment of FIG. 3, during the normal operation period, the first voltage transmitted by the first voltage rail 110 can be the system voltage VDD, and the second voltage transmitted by the second voltage rail 120 can be the ground voltage VSS.

In the embodiment of FIG. 3, the ESD clamp circuit 130 includes a transistor 132 and a NOT gate 133. In the embodiment of FIG. 3, the transistor 132 can be an NMOS transistor, though the invention is not limited thereto. A first terminal (for example, a drain) of the transistor 132 is coupled to the first voltage rail 110, a second terminal (for example, a source) thereof is coupled to the second voltage rail 120, and a third terminal (for example, a gate) thereof is coupled to an output terminal of the NOT gate 133. In the present embodiment, an input terminal of the NOT gate 133 may serve as the control terminal 139 of the ESD clamp circuit 130 to receive the control signal Sc. When the ESD occurs, the control terminal 139 turns on the transistor 132 to provide the ESD current path between the first voltage rail 110 and the second voltage rail 120. In other embodiments, the NOT gate 133 can be replaced by a buffer.

In the embodiment of FIG. 3, the resistive element 150 includes a resistor 151 and a switch circuit 153. The resistor 151 and the switch circuit 153 of FIG. 3 can be deduced with reference of related descriptions of the resistor 151 and the switch circuit 152 of FIG. 2, and details thereof are not repeated. The switch circuit 153 of FIG. 3 includes a driver 301 powered by the first voltage rail 110 and the second voltage rail 120 and a transistor 302. An input terminal of the driver 301 is coupled to the control terminal 139. In the embodiment of FIG. 3, the driver 301 can be a NOT gate circuit. The transistor 302 can be a PMOS transistor, though the invention is not limited thereto. A first terminal (for example, a drain) of the transistor 302 is coupled to the control terminal 139, a second terminal (for example, a source) thereof is coupled to the first voltage rail 110, and a third terminal (for example, a gate) thereof is coupled to an output terminal of the driver 301. In other embodiments, the driver 301 can be a buffer circuit.

During the normal operation period, since the capacitor 140 reaches a stable state (or a fully charged state) to make the control signal Sc to have a high logic voltage, a low logic voltage output by the driver 301 may turn on the transistor 302, such that the capacitor 140 is substantially connected between the first voltage rail 110 and the second voltage rail 120, directly. Therefore, during the normal operation period, the capacitor 140 can be used as a decoupling capacitor. During the ESD period, since the capacitor 140 operated under a transient state may pull down the control signal Sc, a voltage level of the control signal Sc is far lower than a voltage level of the first voltage rail 110, and the high voltage output by the driver 301 may turn off the transistor 302.

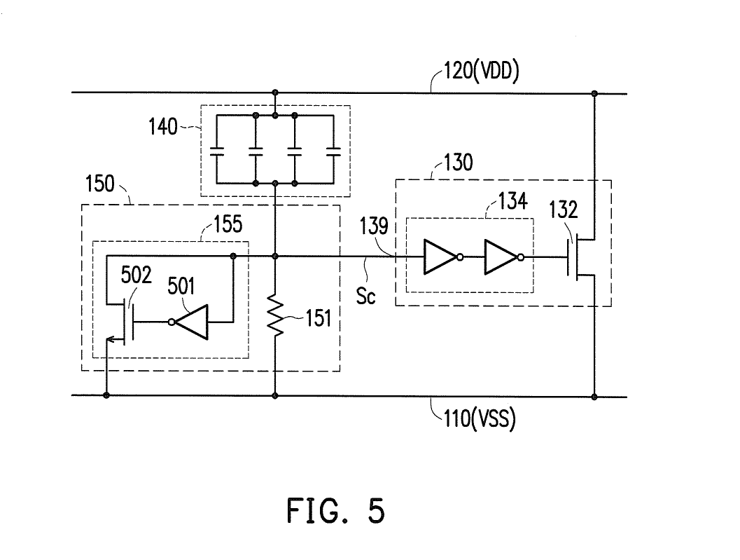

FIG. 4 is a circuit schematic diagram of the ESD clamp circuit 130, the capacitor 140 and the resistive element 150 of FIG. 1 according to still another embodiment of the invention. The capacitor 140 shown in FIG. 4 may refer to related description of the embodiment of FIG. 2, and the ESD clamp circuit 130 of FIG. 4 may refer to related description of the embodiment of FIG. 3, and details thereof are not repeated. In the embodiment of FIG. 4, during the normal operation period, the first voltage transmitted by the first voltage rail 110 can be the system voltage VDD, and the second voltage transmitted by the second voltage rail 120 can be the ground voltage VSS.

In the embodiment of FIG. 4, the resistive element 150 includes a resistor 151 and a switch circuit 154. The resistor 151 and the switch circuit 154 of FIG. 4 can be deduced with reference of related descriptions of the resistor 151 and the switch circuit 152 of FIG. 2, and/or the resistor 151 and the switch circuit 154 of FIG. 4 can be deduced with reference of related descriptions of the resistor 151 and the switch circuit 153 of FIG. 3, and details thereof are not repeated. In the embodiment of FIG. 4, the switch circuit 154 includes a transistor 401. The transistor 401 can be an NMOS transistor, a first terminal (for example, a source) and a third terminal (for example, a gate) of the transistor 401 are commonly coupled to the control terminal 139, and a second terminal (for example, a drain) thereof is coupled to the first voltage rail 110.

FIG. 5 is a circuit schematic diagram of the ESD clamp circuit 130, the capacitor 140 and the resistive element 150 of FIG. 1 according to still another embodiment of the invention. The capacitor 140 shown in FIG. 5 may refer to related description of the embodiment of FIG. 2, and detail thereof is not repeated. In the embodiment of FIG. 5, during the normal operation period, the first voltage transmitted by the first voltage rail 110 can be the ground voltage VSS, and the second voltage transmitted by the second voltage rail 120 can be the system voltage VDD.

In the embodiment of FIG. 5, the ESD clamp circuit 130 includes a transistor 132 and a buffer 134. In the embodiment of FIG. 5, the transistor 132 can be an NMOS transistor, though the invention is not limited thereto. A first terminal (for example, a source) of the transistor 132 is coupled to the first voltage rail 110, a second terminal (for example, a drain) thereof is coupled to the second voltage rail 120, and a third terminal (for example, a gate) thereof is coupled to an output terminal of the buffer 134. In the present embodiment, an input terminal of the buffer 134 may serve as the control terminal 139 of the ESD clamp circuit 130. When the ESD occurs, a cross voltage between two terminals of the resistive element 150 may serve as the control signal Sc. The buffer 134 transmits the control signal Sc to the third terminal of the transistor 132 to electrically turn on the transistor 132. Therefore, during the ESD period, the transistor 132 provides the ESD current path between the first voltage rail 110 and the second voltage rail 120. In the embodiment of FIG. 5, the buffer 134 includes two inverter circuits connected in series to each other. In some other embodiments, the buffer 134 can be a NOT gate circuit, or a known buffer or other buffer circuit.

In the embodiment of FIG. 5, the resistive element 150 includes a resistor 151 and a switch circuit 155. The resistor 151 and the switch circuit 155 of FIG. 5 can be deduced with reference of related descriptions of the resistor 151 and the switch circuit 152 of FIG. 2, and/or the resistor 151 and the switch circuit 155 of FIG. 5 can be deduced with reference of related descriptions of the resistor 151 and the switch circuit 153 of FIG. 3, and details thereof are not repeated. The switch circuit 155 of FIG. 5 includes a driver 501 powered by the first voltage rail 110 and the second voltage rail 120 and a transistor 502. An input terminal of the driver 501 is coupled to the control terminal 139. In the embodiment of FIG. 5, the driver 501 can be a NOT gate circuit. The transistor 502 can be an NMOS transistor, though the invention is not limited thereto. A first terminal (for example, a drain) of the transistor 502 is coupled to the control terminal 139, a second terminal (for example, a source) thereof is coupled to the first voltage rail 110, and a third terminal (for example, a gate) thereof is coupled to an output terminal of the driver 501. In other embodiments, the driver 501 can be a buffer circuit.

During the normal operation period, since the capacitor 140 reaches a stable state (or a fully charged state) to make the control signal Sc of FIG. 5 to have a low logic voltage, a high logic voltage output by the driver 501 may turn on the transistor 502, such that the capacitor 140 is substantially connected between the first voltage rail 110 and the second voltage rail 120, directly. Therefore, during the normal operation period, the capacitor 140 can be used as a decoupling capacitor. During the ESD period, since the capacitor 140 operated under a transient state may pull up the control signal Sc, a voltage level of the control signal Sc of FIG. 5 is far higher than a voltage level of the first voltage rail 110, and the low voltage output by the driver 501 may turn off the transistor 502.

The embodiments of the invention provide the IC 100 and an operation method thereof The operation method includes following step. During the normal operation period, a first voltage and a second voltage are respectively transmitted through the first voltage rail 110 and the second voltage rail 120, and now a resistance of the resistive element 150 is a first resistance. During an ESD period, the IC 100 receives an electrostatic voltage, and now the resistance of the resistive element 150 is a second resistance (where the first resistance is smaller than the second resistance), and the control signal Sc is produced to the control terminal 139, such that the ESD clamp circuit 130 provides at least one ESD current path between the first voltage rail 110 and the second voltage rail 120.

In summary, during the normal operation period, the resistance of the resistive element 150 is the smaller first resistance, such that the capacitor 140 is substantially connected between the first voltage rail 110 and the second voltage rail 120, directly. Therefore, during the normal operation period, the capacitor 140 can be used as the decoupling capacitor. The capacitor 140 can be used to increase a total number of the decoupling capacitors in internal of the IC 100, and decrease a power fluctuation. During the ESD period, the resistance of the resistive element 150 is the larger second resistance. Therefore, during the ESD period, the resistive element 150 and the capacitor 140 coupled in series may inspect whether the first voltage rail 110 or the second voltage rail 120 has an ESD event, so as to determine whether to activate the ESD clamp circuit 130 in time, and accordingly provide the ESD protection function.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An integrated circuit, comprising:
a first voltage rail, transmitting a first voltage during a normal operation period;
a second voltage rail, transmitting a second voltage during the normal operation period;
an electrostatic discharge clamp circuit, having a control terminal, wherein the control terminal receives a control signal during an electrostatic discharge period, such that the electrostatic discharge clamp circuit provides an electrostatic discharge current path between the first voltage rail and the second voltage rail;
a capacitor, coupled between the control terminal and the second voltage rail; and
a resistive element, coupled between the control terminal and the first voltage rail, wherein a resistance of the resistive element is a first resistance during the normal operation period, and the resistance of the resistive element is a second resistance during the electrostatic discharge period, and the first resistance is smaller than the second resistance.

2. The integrated circuit as claimed in claim 1, wherein the electrostatic discharge clamp circuit comprises:
a transistor, having a first terminal, a second terminal and a third terminal, and the first terminal and the second terminal being respectively coupled to the first voltage rail and the second voltage rail; and
a NOT gate, having an input terminal serving as the control terminal of the electrostatic discharge clamp circuit, and an output terminal coupled to the third terminal,
wherein the third terminal electrically turns on a current path between the first terminal and the second terminal according to the control signal during the electrostatic discharge period, so as to provide the electrostatic discharge current path.

3. The integrated circuit as claimed in claim 1, wherein the electrostatic discharge clamp circuit comprises:
a transistor, having a first terminal, a second terminal and a third terminal, and the first terminal and the second terminal being respectively coupled to the first voltage rail and the second voltage rail, wherein the transistor provides the electrostatic discharge current path between the first voltage rail and the second voltage rail during the electrostatic discharge period; and
a buffer, having an input terminal serving as the control terminal, and an output terminal coupled to the third terminal, wherein the third terminal electrically turns on a current path between the first terminal and the second terminal according to the control signal during the electrostatic discharge period, so as to provide the electrostatic discharge current path.

4. The integrated circuit as claimed in claim 1, wherein the electrostatic discharge clamp circuit comprises:
a transistor, having a first terminal, a second terminal and a third terminal, the first terminal and the second terminal being respectively coupled to the first voltage rail and the second voltage rail, and the third terminal serving as the control terminal of the electrostatic discharge clamp circuit, wherein the third terminal electrically turns on a current path between the first terminal and the second terminal according to the control signal during the electrostatic discharge period, so as to provide the electrostatic discharge current path.

5. The integrated circuit as claimed in claim 1, wherein the resistive element comprises:
a resistor, coupled between the control terminal and the first voltage rail; and
a switch circuit, coupled between the control terminal and the first voltage rail, wherein the switch circuit is turned on during the normal operation period, and is turned off during the electrostatic discharge period.

6. The integrated circuit as claimed in claim 5, wherein the switch circuit comprises:
a transistor, having a first terminal, a second terminal and a third terminal, the first terminal and the second terminal being respectively coupled to the control terminal and the first voltage rail, and the third terminal being controlled by a power-up signal of the integrated circuit, wherein during the normal operation period, the third terminal receives the power-up signal to turn on the transistor.

7. The integrated circuit as claimed in claim 5, wherein the switch circuit comprises:
a driver, having an input terminal coupled to the control terminal; and
a transistor, having a first terminal, a second terminal and a third terminal, the first terminal and the second terminal being respectively coupled to the control terminal of the electrostatic discharge clamp circuit and the first voltage rail, and the third terminal being coupled to an output terminal of the driver.

8. The integrated circuit as claimed in claim 5, wherein the switch circuit comprises:
a transistor, having a first terminal, a second terminal and a third terminal, the first terminal and the third terminal being coupled to the control terminal, and the second terminal being coupled to the first voltage rail.

9. An operation method of an integrated circuit, wherein the integrated circuit comprises a first voltage rail, a second voltage rail, an electrostatic discharge clamp circuit, a capacitor and a resistive element, the electrostatic discharge clamp circuit is coupled between the first voltage rail and the second voltage rail, the resistive element is coupled between the first voltage rail and a control terminal of the electrostatic discharge clamp circuit, and the capacitor is coupled between the second voltage rail and the control terminal of the electrostatic discharge clamp circuit, the operation method comprising:
respectively transmitting a first voltage and a second voltage through the first voltage rail and the second voltage rail during a normal operation period, wherein a resistance of the resistive element is a first resistance during the normal operation period; and
receiving an electrostatic voltage by the integrated circuit during an electrostatic discharge period, wherein during the electrostatic discharge period, the resistance of the resistive element is a second resistance, and a control signal is produced to the control terminal, such that the electrostatic discharge clamp circuit provides an electrostatic discharge current path between the first voltage rail and the second voltage rail,
wherein the first resistance is smaller than the second resistance.

10. The operation method of the integrated circuit as claimed in claim 9, wherein during the normal operation period, the first resistance makes the capacitor to be substantially connected between the first voltage rail and the second voltage rail, directly.
